(19) United States
(12) Patent Application Publication
(10) Pub. No.: US 2024/0112999 A1
(43) Pub. Date: Apr. 4, 2024

(54) LAYERED GLASS ASSEMBLY WITH PRE-PATTERNED ELECTRICALLY CONDUCTIVE INTERCONNECTS

(71) Applicant: Intel Corporation, Santa Clara, CA (US)

(72) Inventors: Jieying Kong, Chandler, AZ (US); Houssam Jomaa, San Diego, CA (US); Dilan Seneviratne, Phoenix, AZ (US); Whitney Bryks, Tempe, AZ (US); Srinivas Venkata Ramanuja Pietambaram, Phoenix, AZ (US); Kristof Darmawikarta, Chandler, AZ (US)

(21) Appl. No.: 17/955,689

(22) Filed: Sep. 29, 2022

(51) Int. Cl. H01L 23/498; H01L 21/48

(52) U.S. Cl. CPC H01L 23/49822; H01L 21/4857; H01L 21/486; H01L 23/49894

(57) ABSTRACT

An electronic system comprising can have a substrate with a core layer formed from at least one layer of glass. The glass layers can each be stacked with a dielectric material disposed between each layer of glass. The glass layers can be prepatterned before assembly of the layered glass core system.

### TECHNICAL FIELD

This document pertains generally, but not by way of limitation, to electronic substrates such as those formed from at least one layer of glass as a core which has been prepatterned with electrically conductive interconnects.

### BACKGROUND

A substrate is a base layer which forms the structure for a chip, printed circuit board, or the like. Materials which have thermal and mechanical stable properties are usually selected to form the substrate. Silicon is the most commonly used material for a chip or the substrate, but other materials such as glass, plastic or other metals are known in the industry as being suitable for the substrate as well.

Materials which can form a solid structure, that is substantially unchanged by applied pressures and which are substantially non-conductive can be a desired material for a core, or other layers laminated or placed proximate to the core of the substrate. An example material for a core can be glass.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIGS. 1A and 1B are each an illustration of a glass core layer according to at least one example of the present disclosure.

FIG. 2 is an illustration of an exploded view of an assembled glass core layer according to at least one example of the present disclosure.

FIGS. 3A-3C is an illustration of a process for forming an assembled glass core layer according to at least one example of the present disclosure.

FIG. 4 is an illustration an assembled glass core layer according to at least one example of the present disclosure

FIG. 5 illustrates a system level diagram, depicting an example of an electronic device (e.g., system) including a substrate containing a magnetic inductor device.

### DETAILED DESCRIPTION

Some substrates for computer chips or other electrical systems can have a core, for example a resin core. A resin core can be made from a polymer resin. The resin core can also have fiberglass dispersed throughout. The core can be the foundation on which other layers made from the same or similar materials, or other components of a chip can be coupled or built up.

The resin core can have layers of a dielectric material coupled to upper or lower surfaces of the resin core. The resin core can also have a conductive material coupled to the surfaces, such as a copper layer or copper foil. However, any conductive material suitable for the purpose may be used. Though holes can be formed through the resin core. Further, layers coupled to the resin core to form stacked layers with electrically conductive interconnects applied, coupled or formed on the surfaces of the layers.

Resin as a core material and dielectric materials coupled to the resin core material, in some situations, can be a deformable material. Polymers in the resin core or in the dielectric material can deform when subjected to applied pressures or fluctuations in temperature. Deformation to resin cores and dielectric materials can be expansion or contraction of the material in lateral directions. Deformation can also be compression or expansion in a depth direction such that the resin core or the dielectric material is compressed or expanded. The deformation can also be undulations, ripples or uneven thicknesses in the resin core material. Both applied pressures and fluctuations are known environmental conditions during manufacturing of computer chips which can cause changes in dimensions of the resin core or dielectric material and changes in the location of the components coupled to or formed in or with the resin core.

The present inventors have recognized a need for layers within a substrate, core or computer chip which can be a solid (e.g., nondeformable, fixed, rigid or the like) structure which, when subjected to changes in environmental conditions and does not experience significant changes to material properties. The present inventors have recognized the need for a material for layers which can remain substantially constant so any components, such as additional layers, though holes or conductive materials can remain substantially in place.

An example of a material which can be used to form solid (e.g., nondeformable, fixed, stable or the like) structure for a layer can be glass, or a glass-like material. The glass layer can also be a core upon which other layers, or components can be stacked. The glass layer can be a central core for a substrate or chip, or the glass layer can be an individual core which is not central, but instead at a different location within the layers of the substrate or chip. Glass is generally known to be a material which is rigid. Glass can also be a material which is not easily deformed when subjected to changes in environmental conditions. For example, when glass is exposed to pressures it does not easily change in structure. When glass is exposed to pressures it usually does not compress or expand in thickness, or a depth direction.

Glass can be a material which is known to have flat, even or level surfaces. Both sides of a glass surface (e.g., upper and lower or opposing sides if oriented in a different configuration) can be substantially flat or just one side of a sheet or piece of glass can be substantially flat as well while the other side can have ripples, undulations or other irregularities in the surface texture. When using glass, or a similar material, for a core layer having a flat, even or level surface (i.e., a surface without ripples, undulations, protrusions, indentations or the like) can be beneficial for accurate placement of through holes, electrically conductive interconnects or any other component which may be desired or necessary.

Glass can be a material which has a known thermal and mechanical stability. Glass can be considered as a next generation substrate material which can assist in achieving approximately true position and minimize thickness variation during, for example, a layering process flow.

The thermal mechanical benefits of glass materials can be a benefit to glass which can be layered. Such thermal mechanical benefits can minimize undulations which can occur when layers are compressed or stacked on previous layers. In other words, the thermal mechanical qualities of glass can result in the glass retaining substantially an original shape or dimensions. The thermal and mechanical quantities of glass can also result in minimization of the occurrence of shrinkage when further layers are stacked. The thermal mechanical qualities of glass can also be beneficial when adding conductive materials, such as copper, to the surface of the glass.

The glass core layer can include a silicate-based glass (e.g., lithium-silicate, borosilicate, aluminum silicate, etc.). In variations, the glass of the glass core layer can be a lower quality glass (e.g., glass made with soda lime), or a higher quality glass (e.g., glass made with fused silica). Glass can be a material with low conductivity and one which can minimize migration of conductive materials across surfaces or within the core material. Conductive materials, such as copper, during manufacturing of the core, or chip, can migrate across surfaces and damage or coat other components of the core or chip. When migration occurs, affected components are known in some instances to not function efficiently or effectively.

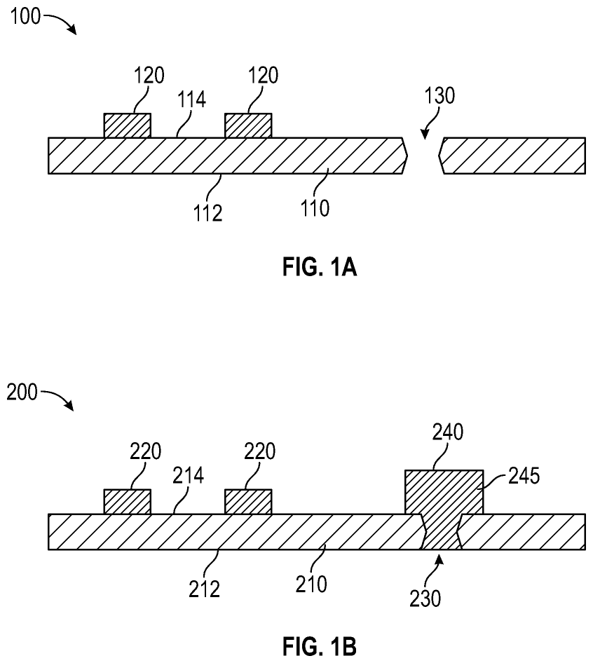

In an example for a glass core 110 (or glass core layer) for use as a glass layer 100 is illustrated in FIG. 1A. Glass core 110 can refer to as the base or foundation on which further layers (glass or other materials used in a substrate or a chip) can be stacked, components can be adhered, coupled, attached or the like and through which indentations, holes, passages and the like can be formed. The glass layer 100 can have the glass core 110 as a support for at least one electrically conductive interconnect 120. The at least one electrically conductive interconnect 120 can be formed from copper, aluminum, gold, or any other material which can provide a pathway to transmit an electrical signal. The at least one electrically conductive interconnect 120 can refer to a copper trace, copper pad or any interconnect or pad formed from any conductive material suitable for the purpose of the core, substrate or glass layer 100.

As illustrated in FIGS. 1A and 1B, at least one electrically conductive interconnect 120 (herein traces will refer to any electrically conductive interconnect formed from any suitable material) can be formed or coupled to the upper surface 114 of the glass core 110. The electrically conductive interconnect 120 can be formed at any location on the glass core 110 which is suitable for the purpose of the glass layer 100.

The glass core 110 can also have a through hole 130 which passes from an upper surface 114 of the glass core 110 to a lower surface 112 of the glass core 110. A through hole, such as through hole 130, can be a component of the mounting structure or scheme. The though hole 130 can provide an area of the glass core 110 where electronic components, such as leads, can be inserted or passed through.

The glass layer 100 can be a component of a glass layer system, assembly or structure. The glass layer 100 can be an example of a subsequent layer glass core which can be added to the glass core system according to the number of layers which can be required for the specified purpose. The glass layer 100 can also be referred to as a subsequent layer glass core 100.

The glass layer 200 (or glass core layer) can be another example of the glass core 210 with electrically conductive interconnects 220 as an underlying layer on which other glass layers can be stacked. The glass core 210 can have electrically conductive interconnects 220 formed or placed on an upper surface of the glass core 210. The electrically conductive interconnects 220 can be formed similar to the electrically conductive interconnects 120 of the glass core 110 illustrate in FIG. 1A. The electrically conductive interconnects 220 can be coupled to or formed with the glass core 210 in any manner and at any location suitable for the purpose.

The glass core 210 can have a through hole 230 which can pass from an upper surface 214 of the glass core 210 to the lower surface 212 of the glass core 210. The glass core 210 can be filled with a copper fill 240, or any conductive material suitable for the purpose. The copper fill 240 can completely or partially the through hole 230. The copper fill 240 can extend outside of the through hole 230. When the copper fill 240 extends outside of the through hole 230, for example, on the upper surface 214 of the glass core 210, a copper pad 245 can be formed.

The glass core 110 illustrated in FIG. 1A and the glass core 210 illustrated in FIG. 1B can be prepatterned with electrically conductive interconnects 120, 220 and through holes 130, 230. Sheets of glass layers 100, 200 can be formed or manufactured with several individual glass cores 110, 210 prepatterned in a way that individual glass cores 110, 210 can be separated as necessary. Using prepatterned glass cores 110, 210 can reduce process steps or can reduce costs of the ultimate product. Prepatterned glass cores 110, 210 can also result in a consistently flat upper surface 114, 214 and lower surface 112, 212.

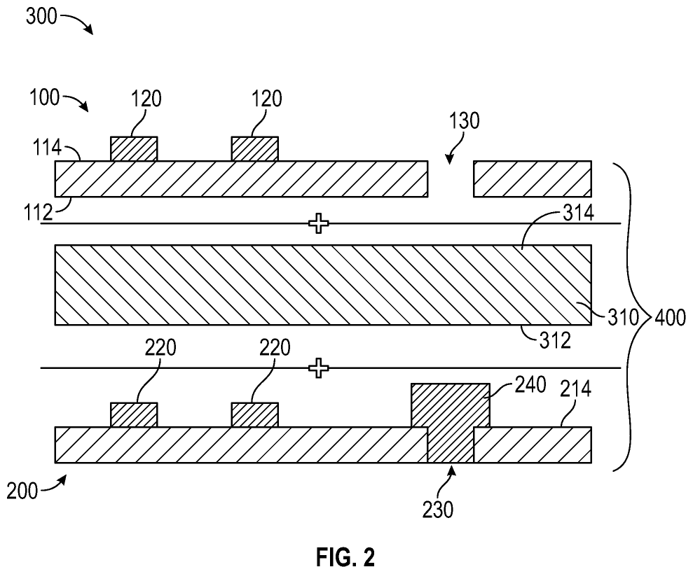

An exemplary electrical system or layered glass core system 300, as illustrated in FIG. 2, can have an underlying layer formed from a glass core (or glass core layer). The glass core 200 can be an underlying layer glass core and can be the underlying layer with electrically conductive interconnects 220 disposed on the upper surface 214 and the through hole 230. The through hole 230 of the underlying layer, or underlying layer glass core 200, can be filled with copper fill 240. The layered glass core system 300 can have a layer of a dielectric material 310 disposed on the upper surface 214 of the underlying layer glass core 200. The dielectric material 310 can be Ajinomoto Build-Up Film®, or a similar material.

The dielectric material 310 can be sandwiched between the underlying layer glass core 200 and a subsequent, upper glass layer such as subsequent layer glass core 100. The glass layer 100 can have electrically conductive interconnects 120 disposed, or placed, on the upper surface 114 of the glass layer and the lower surface 312 of the dielectric material 310 can be connected, or coupled with, the lower surface 112 of the subsequent layer glass core 100. The dielectric material 310 can be affixed, connected or coupled with the upper surface 214 of the glass core 210 with a silicon nitride or other adhesion promotor materials. Similarly, the lower surface 112 of the subsequent layer glass core 100 can be affixed, connected or coupled with the upper surface 314 of the dielectric layer. While silicon nitride can be used to affix, connect or couple the dielectric material with the glass core 110, 210 any material suitable for the purpose can be used.

The underlying glass layer core 200, the dielectric material 310 and the subsequent (or second) layer glass core 100 can substantially overlap, or be aligned before being coupled, or connected, together. The layers can be substantially aligned (herein aligned can refer to substantially overlapping) within about 10 μm. Alignment marks can be placed on the surface of the glass core 110, 210 can be used to align the underlying layer glass core 200 with the subsequent layer glass core 100. In another example, a location of the through hole 230 of the underlying layer glass core 200 with a location of a corresponding through hole 130 of the subsequent layer glass core 100 can be used to align the underlying layer glass core 200 with the subsequent layer glass core 100. The dielectric material 310 can be placed, coupled or sandwiched between the underlying layer glass core 200 and the subsequent layer glass core 100.

The glass core layered system 300 with the underlying layer glass core 200, the dielectric material 310 and the subsequent layer glass core 100 can be considered, when coupled together, another form of an underlying layer (an assembled underlying layer). The assembled underlying layer glass core 400 can then be used as a base layer for more subsequent layer glass cores 100 to be coupled to the upper surface 314 of the dielectric material 310. Between each assembled underlying layer glass core 400 and the next subsequent layer glass core 100 can be another dielectric material 310. The number of subsequent layer glass cores 100 used can be dependent on the purpose and use of the electronic system.

Dielectric material 310 can protrude, expand or fill the through hole 130 of the subsequent layer glass core 100 due to the viscoelasticity of the dielectric material. For example, if 8 layers are necessary for a core, then there can be 1 underlying layer glass core 200 and 7 subsequent layer glass cores 100 totaling 8 layers of glass cores. In another example, if 16 layers are necessary for a core, then there can be 1 underlying layer glass core 200 and 15 subsequent layer glass cores 100.

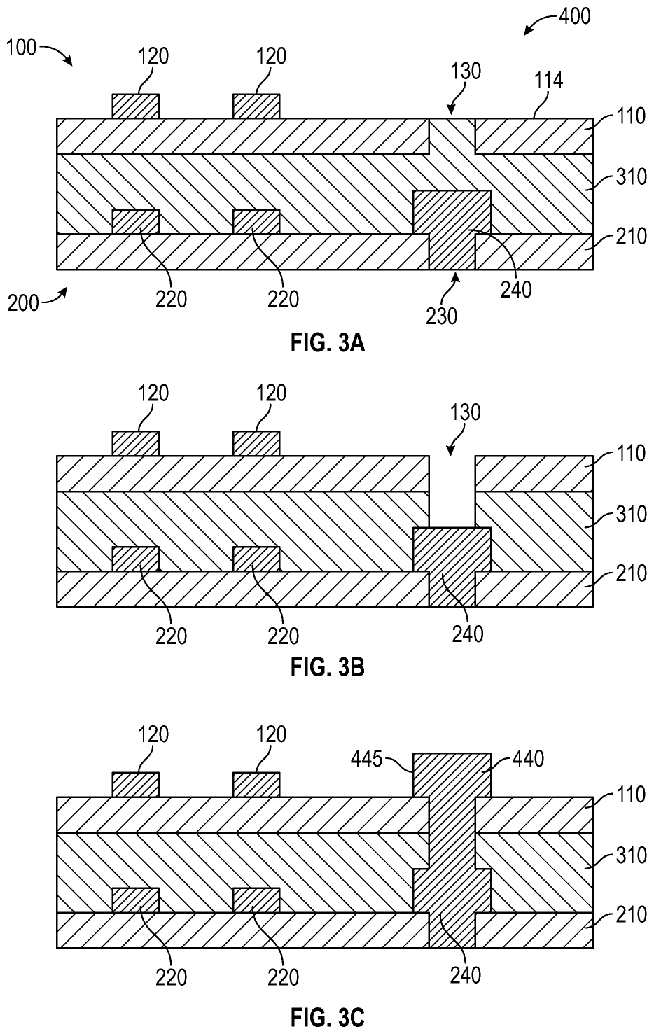

An example of a process for forming a multi-layered core structure as contemplated by the present disclosure is illustrated in FIGS. 3A-C. The multi-layered core structure can begin with an underlying layer glass core 200 which has been prepatterned. An underlying layer glass core 200 can be formed from a part of a prepatterned section of an underlying glass core sheet or individually as a glass core 210 which is sized for the specified purpose. The glass core 210 of the underlying layer glass core 200 can be prepatterned with electrically conductive interconnects 220. The electrically conductive interconnects 220 can be formed from any conductive material such as copper, aluminum, gold, or another conductive material. The glass core 210 can also have at least one through hole 230 formed within the glass core 210. The at least one through hole 230 can be at least partially filled with a copper fill 240. The at least one through hole 230 can be overfilled with copper fill 240 so a copper pad can be formed on an upper surface 214 of the glass core 210.

A subsequent layer glass core 100 can be formed with electrically conductive interconnects 120 coupled to an upper surface 114 of the glass core 110. A subsequent layer glass core 100 can be formed from a part of a prepatterned section of a subsequent layer glass core sheet or individually as a glass core 110 which is sized for the specified purpose. The electrically conductive interconnects 120 can be formed from any conductive material such as copper, aluminum, gold, or another conductive material. The glass core 110 can also have a through hole 130 formed at a specified location. The through hole 130 can be in a similar location as the through hole 230 in the underlying layer glass core 200. The through hole 130 in the glass core 110 and the through hole 230 in the glass core 210, when stacked, can be in an configuration where the through holes are substantially overlapping or at least partially overlapping. In another configuration, the through holes can be substantially aligned.

When forming the multi-layered, assembled underlying layer glass core 400, the underlying layer glass core 200 can be placed on the bottom with the upper surface 214 oriented in an upward facing direction with the electrically conductive interconnects 220 facing upward. A layer of dielectric material 310 can be placed, coupled or connected to the upper surface 214 of the underlying layer glass core 200. A lower surface 312 of the dielectric material 310 can be placed on, coupled with (hereinafter coupled) or connected to the upper surface 214 of the underlying layer glass core 200. The dielectric material 310 can be coupled with the upper surface 214 with silicon nitride, or a similar material which can be used to adhere the dielectric material 310 and the underlying layer glass core. The upper surface 314 of the dielectric material layer 310 can be coupled with the lower surface 112 of the subsequent layer glass core 100. Silicon nitride can be disposed on the lower surface 112 of the subsequent layer glass core 100 to assist in adhering the subsequent layer glass core 100 with the dielectric material 310.

When the subsequent layer glass core 100, the dielectric material 310 and the underlying layer glass core 200 are coupled together, the components (electrically conductive interconnects, through holes, etc.) and the edges of each layer 100, 310, 200 can be substantially aligned. The layers 100, 310 and 200 can then be pressed or otherwise joined together.

The dielectric material 310, when pressed or otherwise coupled with the subsequent layer glass core 100, some of the dielectric material can protrude or be forced through the at least one through hole 130. The dielectric material can at least partially fill the at least one through hole 130. The dielectric material can then be cleaned or removed from the through hole 130 by drilling or other action to remove material. The dielectric material can be removed from the through hole 130, as illustrated in FIG. 3B, until the drill substantially meets the copper fill 240 in the through hole 230 of the underlying layer glass core 200.

When the dielectric material has been removed from the through hole 130, a desmear process can be taken to remove any remaining material or other debris from the through hole 130. An electroless process can be taken, such as depositing a copper or copper-titanium alloy. This can assist in deposition of electroless copper when forming a current path for elytic copper deposition.

An electrically conductive material 440, such as copper, gold, aluminum, or the like, can be deposited or filled in the through hole 130, as illustrated in FIG. 3C. The electrically conduct material 440 can at least partially fill the through hole 130 or completely fill the through hole 130. The electrically conductive material 440 can also overfill the through hole 130 such that an electrically conductive pad of material 445 is deposited or formed on the upper surface 114 of the glass core 110.

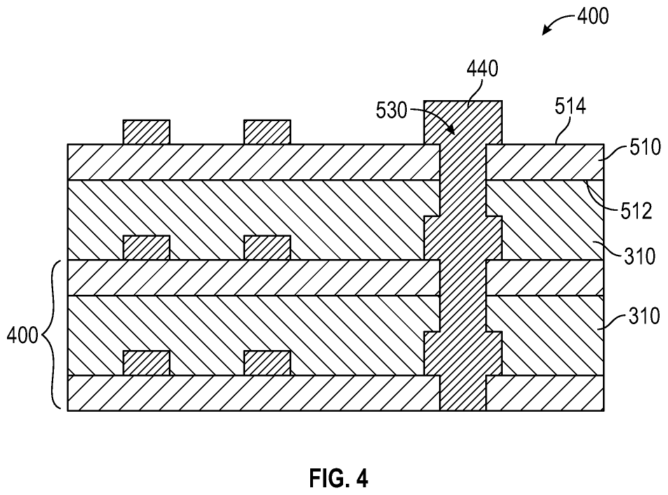

The above process can be repeated with the assembled underlying layer glass core 200, dielectric material 310, and subsequent layer glass core 100 as an assembled underlying layer glass core 400. As illustrated in FIG. 4, another layer of dielectric material 310 can be coupled to the upper surface 114 of the subsequent layer glass core 100 and a lower surface 512 of another subsequent layer glass core 510. A through hole 530 can have the dielectric material removed, which at least partially filled the through hole 530 when the subsequent layer glass core 510 is pressed on top of the assembled underlying layer glass core 400. Then the through hole 530 can be cleaned, coated with an electroless material, and then at least partially filled with an electrically conductive material 440. This process can be repeated as many times as necessary for the number of layers required for the specified purpose.

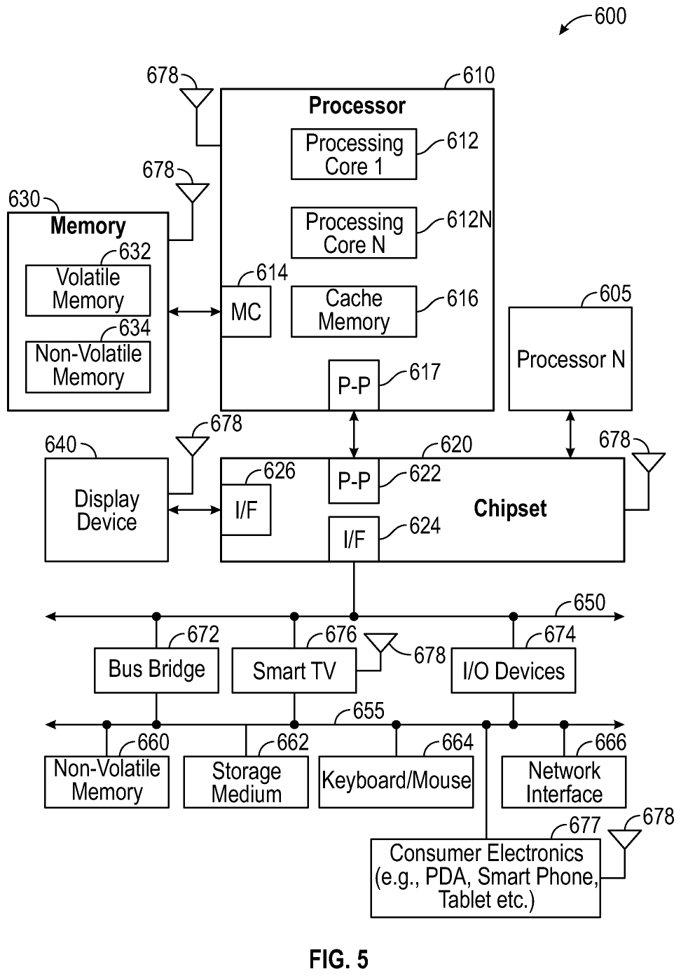

FIG. 5 illustrates a system level diagram, depicting an example of an electronic device (e.g., system) that may include a substrate containing a core formed from glass layers and which is formed, for example, from any of the example process flows described above. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 600 includes a system on a chip (SOC) system.

In one embodiment, processor 610 has one or more processor cores 612 and 612N, where 612N represents the Nth processor core inside processor 610 where N is a positive integer. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, which is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, an interface for wireless antenna 678 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random-access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments of the example system, interfaces 617 and 622 operate in accordance with a PtP communication protocol such as the Intel® QuickPath Interconnect (QPI) or the like. In other embodiments, a different interconnect may be used.

In some embodiments, chipset 620 is operable to communicate with processor 610, 605N, display device 640, and other devices, including a bus bridge 672, a smart TV 676, I/O devices 674, nonvolatile memory 660, a storage medium (such as one or more mass storage devices) 662, a keyboard/mouse 664, a network interface 666, and various forms of consumer electronics 677 (such as a PDA, smart phone, tablet etc.), etc. In one embodiment, chipset 620 couples with these devices through an interface 624. Chipset 620 may also be coupled to a wireless antenna 678 to communicate with any device configured to transmit and/or receive wireless signals. In one example, any combination of components in a chipset may be separated by a continuous flexible shield as described in the present disclosure.

Chipset 620 connects to display device 640 via interface 626. Display 640 may be, for example, a liquid crystal display (LCD), a light emitting diode (LED) array, an organic light emitting diode (OLED) array, or any other form of visual display device. In some embodiments of the example system, processor 610 and chipset 620 are merged into a single SOC, in other embodiments, processor 610 and chipset 620 may be part of a disaggregated collection of discrete dies (e.g., chiplets, tiles, etc.) interconnected into a single package assembly. In addition, chipset 620 connects to one or more buses 650 and 655 that interconnect various system elements, such as I/O devices 674, nonvolatile memory 660, storage medium 662, a keyboard/mouse 664, and network interface 666. Buses 650 and 655 may be interconnected together via a bus bridge 672.

In one embodiment, mass storage device 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 5 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612.

### Various Notes and Aspects

Aspect 1 can include a semi conductor device with an underlying glass layer with an upper surface and a lower surface. The glass layer can include at least one electrically conductive interconnect disposed on the upper surface of the glass layer and at least one through hole within the glass layer. The glass layer can extend from the upper surface to the lower surface.

Aspect 2 can include, or can optionally be combined with the subject matter of Aspect 1, to optionally include an electrically conductive fill in the at least one through hole.

Aspect 3 can include, or can optionally be combined with the subject matter of any of the preceding aspects, to optionally include a dielectric layer coupled to at least one of the upper surface or the lower surface.

Aspect 4 can include, or can optionally be combined with the subject matter of any of the preceding aspects, to optionally include a subsequent glass layer core coupled to an upper surface of the dielectric layer. The dielectric layer can be sandwiched between the underlying glass layer core and the subsequent layer glass core.

Aspect 5 can include, or can optionally be combined with the subject matter of any of the preceding aspects, to optionally include a subsequent glass core layer having at least one copper trace and at least one through hole. The at least one through hole of the subsequent glass layer core can be at least partially overlapping or substantially aligned with the through hole of the underlying glass layer core.

Aspect 6 can include, or can optionally be combined with the subject matter of any of the preceding aspects, to optionally include the glass core as one of a plurality of glass cores. The dielectric layer can be one of a plurality of dielectric layers and each dielectric layer of the plurality of dielectric layers can be sandwiched between a subsequent glass layer core and one of the plurality of glass cores.

Aspect 7 can include, or can optionally be combined with the subject matter of any of the preceding aspects, to optionally include glass core can be at least partially overlapping or substantially aligned with at least one of a preceding glass core or a subsequent glass core.

Aspect 8 can include, or can optionally be combined with the subject matter of any of the preceding aspects, to optionally include at least one electrically conductive material can be copper, aluminum or gold.

Aspect 9 can include an electronic system comprising a semiconductor chip coupled to a package substrate. The package substrate can include at least one underlying layer glass core with a glass core, at least one electrically conductive interconnect and at least one electronic transmission hole extending from an upper surface of the glass core layer through the glass core layer to a lower surface of the glass core layer. The package substrate can also include at least one subsequent layer glass core with a glass core, at least one electrically conductive interconnect and at least one electronic transmission hole extending from an upper surface of the glass core through the glass core layer to a lower surface of the glass core layer. The at least one dielectric layer can be sandwiched between the at least one underlying layer glass core and the at least one subsequent layer glass core.

Aspect 10 can include, or can optionally be combined with the subject matter of Aspect 9, to optionally include copper plating within the at least one electronic transmission hole in at least one of the underlying layer glass core or the at least one subsequent layer glass core.

Aspect 11 can include, or can optionally be combined with the subject matter any of Aspects 9 and 10, to optionally include the at least one dielectric layer can be coupled to the upper surface of the glass core layer or the lower surface of the glass core layer with silicon nitride.

Aspect 12 can include, or can optionally be combined with the subject matter any of Aspects 9 and 11, to optionally include at least one dielectric layer coupled to the upper surface of the glass core layer or the lower surface of the glass core layer with pressing and curing.

Aspect 13 can include, or can optionally be combined with the subject matter any of Aspects 9 and 12, to optionally include the package substrate includes a plurality of alternating layers of the at least one glass core and the at least one dielectric layer.

Aspect 14 can include, or can optionally be combined with the subject matter any of Aspects 9 and 13, to optionally include each of the at least one glass core is at least partially overlapping or substantially aligned with at least one of a subsequent layer glass core or the underlying layer glass core.

Aspect 15 can include a method for making an electronic system comprising forming an underlying layer glass core with at least one electrically conductive interconnect on an upper surface of the underlying layer glass core and at least one through hole. The at least one through hole extends from an upper surface of the to a lower surface of the underlying layer glass core. The method can also include forming a subsequent layer glass core with at least one electrically conductive interconnect coupled to an upper surface of the subsequent layer glass core and at least one through hole in the subsequent layer glass core. The at least one through hole extends from an upper surface of the to a lower surface of the subsequent layer glass core. The method can also include filling the at least one through hole of the subsequent glass core layer with an electrically conductive material. The method can further include aligning the through hole of the underlying layer glass core with the through hole of the subsequent layer glass core and coupling a dielectric layer to the lower surface of the subsequent layer glass core and to the upper surface of the underlying layer glass core. The method can include pressing the subsequent layer glass core and underlying layer glass core together, sandwiching the dielectric layer. The dielectric layer is pressed into the through hole of the subsequent layer glass core. The method can include removing dielectric material from the through hole of the subsequent layer glass core. The method can also include filling the through hole with an electrically conductive material.

Aspect 16 can include, or can optionally be combined with the subject matter any Aspect 15, to optionally include the steps of coupling the dielectric material with at least one of the subsequent layer glass core, removing dielectric material from the through hole, and filling the through hole with the electrically conductive material is repeated a predetermined number of times.

Aspect 17 can include, or can optionally be combined with the subject matter of any of Aspects 15 or 16, to optionally include the electrically conductive material is copper.

Aspect 18 can include, or can optionally be combined with the subject matter of any of the Aspects 15 to 17 where each of the underlying layer glass core and the subsequent layer glass core are at least partially overlapping or substantially aligned.

Aspect 19 can include, or can optionally be combined with the subject matter of any of the Aspects 15 to 18 where the method can further include applying silicon nitride to a surface facing the dielectric material.

Aspect 20 can include, or can optionally be combined with the subject matter of any of the Aspects 15 to 19 where the method can further include identifying a location of the through hole with lithography.

Each of these non-limiting aspects can stand on its own, or can be combined in various permutations or combinations with one or more of the other aspects.

The above description includes references to the accompanying drawings, which form a part of the detailed description. The drawings show, by way of illustration, specific embodiments in which the embodiments can be practiced. These embodiments are also referred to herein as “aspects” or “examples.” Such aspects or example can include elements in addition to those shown or described. However, the present inventors also contemplate aspects or examples in which only those elements shown or described are provided. Moreover, the present inventors also contemplate aspects or examples using any combination or permutation of those elements shown or described (or one or more features thereof), either with respect to a particular aspects or examples (or one or more features thereof), or with respect to other Aspects (or one or more features thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Geometric terms, such as “parallel”, “perpendicular”, “round”, or “square”, are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

The above description is intended to be illustrative, and not restrictive. For example, the above-described aspects or examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as aspects, examples or embodiments, with each claim standing on its own as a separate embodiment, and it is contemplated that such embodiments can be combined with each other in various combinations or permutations. The scope of the embodiments should be determined with reference to the appended claims, along with the full scope of equivalents to which such claims are entitled.

What is claimed is:

1. A semiconductor device comprising:
an underlying glass layer with an upper surface and a lower surface, the glass layer including:
at least one electrically conductive interconnect disposed on the upper surface of the glass layer; and
at least one through hole within the glass layer extending from the upper surface to the lower surface.

2. The semiconductor device of claim 1, further comprising an electrically conductive fill in the at least one through hole.

3. The semiconductor device of claim 1, further comprising a dielectric layer coupled to at least one of the upper surface or the lower surface.

4. The semiconductor device of claim 3, further comprising a second glass layer coupled to an upper surface of the dielectric layer;
wherein the dielectric layer is sandwiched between a first underlying glass layer and the second glass layer.

5. The semiconductor device of claim 1, further comprising a subsequent glass layer having at least one copper trace and at least one through hole;
wherein the at least one through hole of the subsequent glass layer is at least partially overlapping with the through hole of the underlying glass layer.

6. The semiconductor device of claim 1, wherein the underlying glass layer is one of a plurality of glass layers;
wherein a dielectric layer is one of a plurality of dielectric layers; and
wherein each dielectric layer of the plurality of dielectric layers is sandwiched between a subsequent glass layer and one of the plurality of glass layers.

7. The semiconductor device of claim 6, wherein each glass layer is substantially aligned with at least one of a preceding glass layer or the subsequent glass layer;
wherein the aligned glass layers forms a glass core.

8. The semiconductor device of claim 1 wherein the at least one electrically conductive interconnects is formed from copper, aluminum or gold.

9. An electronic system comprising:
a semiconductor chip coupled to a package substrate;
the package substrate including:
at least one underlying glass core layer with a glass core, at least one electrically conductive interconnect and at least one electronic transmission hole extending from an upper surface of the glass core layer through the glass core layer to a lower surface of the glass core layer;
at least one subsequent glass core layer with a glass core, at least one electrically conductive interconnect and at least one electronic transmission hole extending from an upper surface of the glass core through the glass core layer to a lower surface of the glass core layer; and
at least one dielectric layer sandwiched between the at least one underlying glass core layer and the at least one subsequent glass core layer.

10. The electronic system of claim 9, further including:
copper plating within the at least one electronic transmission hole in at least one of the underlying glass core layer or the at least one subsequent glass core layer.

11. The electronic system of claim 9, wherein the at least one dielectric layer is coupled to the upper surface of the glass core layer or the lower surface of the glass core layer with silicon nitride.

12. The electronic system of claim 9, wherein the at least one dielectric layer is coupled to the upper surface of the glass core layer or the lower surface of the glass core layer with pressing and curing.

13. The electronic system of claim 9, wherein the package substrate includes a plurality of alternating layers of the at least one glass core layer and the at least one dielectric layer.

14. The electronic system of claim 13, wherein each of the at least one glass core layer is substantially aligned with at least one of a subsequent glass core layer or the underlying layer glass core.

15. A method for making an electronic system comprising:
forming an underlying layer glass core with at least one electrically conductive interconnect on an upper surface of the underlying layer glass core and at least one through hole;
wherein the at least one through hole extends from an upper surface of the to a lower surface of the underlying layer glass core;
forming a subsequent layer glass core with at least one electrically conductive interconnect coupled to an upper surface of the subsequent layer glass core and at least one through hole in the subsequent layer glass core;
wherein the at least one through hole extends from an upper surface of the to a lower surface of the subsequent layer glass core;
filling the at least one through hole of the subsequent glass core layer with an electrically conductive material;
aligning the through hole of the underlying layer glass core with the through hole of the subsequent layer glass core;
coupling a dielectric layer to the lower surface of the subsequent layer glass core and to the upper surface of the underlying layer glass core;
pressing the subsequent layer glass core and underlying layer glass core together, sandwiching the dielectric layer;
wherein the dielectric layer is pressed into the through hole of the subsequent layer glass core;
removing dielectric material from the through hole of the subsequent layer glass core; and
filling the through hole with an electrically conductive material.

16. The method for making the electronic system of claim 15, wherein the steps of coupling the dielectric material with at least one of the subsequent layer glass core, removing the dielectric material from the through hole, and filling the through hole with the electrically conductive material is repeated a predetermined number of times.

17. The method for making the electronic system of claim 15, wherein the electrically conductive material is copper.

18. The method for making the electronic system of claim 15, wherein each of the underlying layer glass core and the subsequent layer glass core are aligned.

19. The method for making the electronic system of claim 15, further comprising applying silicon nitride to a surface facing the dielectric material.

20. The method for making the electronic system of claim 15, identifying a location of the through hole with lithography.
